(19) United States
(12) Patent Application Publication
(10) Pub. No.: US 2009/0283138 A1
(43) Pub. Date: Nov. 19, 2009

(54) HIGH PERFORMANCE OPTOELECTRONIC DEVICE

(75) Inventors: Chiung-Wei Lin, Taipei (TW); Yi-Liang Chen, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignees: TATUNG COMPANY, Taipei (TW); TATUNG UNIVERSITY, Taipei (TW)

(21) Appl. No.: 12/202,348

(22) Filed: Sep. 1, 2008

(30) Foreign Application Priority Data
May 19, 2008 (TW) 97118368

(51) Int. Cl. H01L 31/0336

(52) U.S. Cl. 136/255; 257/E31.005

(57) ABSTRACT

An optoelectronic device is provided. The optoelectronic device includes a P-type semiconductor substrate, an N-type transparent amorphous oxide semiconductor (TAOS) layer located on a surface of the P-type semiconductor substrate, and a rear electrode on another surface of the P-type semiconductor substrate. The N-type TAOS layer constructs a portion of a P-N diode, and serves as a window layer and a front electrode layer.

### CROSS-REFERENCE TO RELATED APPLICATION

This application claims the priority benefit of Taiwan application serial no. 97118368, filed on May 19, 2008. The entirety of the above-mentioned patent application is hereby incorporated by reference herein and made a part of specification.

### BACKGROUND OF THE INVENTION

1. Field of the Invention

The present invention relates to a diode adapted for an optoelectronic device and a solar cell using the diode.

2. Description of Related Art

A solar cell is capable of directly converting solar energy into electricity. When it comes to pollutions and the shortage of fossil fuel, the development of solar cells is brought into focus.

A solar cell generates photo-electricity mainly through photo-voltaic effect. Generally, a photo-voltaic effect refers to an effect that two end electrodes of a P—N diode generate an output voltage after photons are infused to the P—N diode to generate current.

In a typical solar cell, an N-type-doped layer is formed on a P-type silicon substrate by diffusion, and then a front electrode and a rear electrode are formed at both sides of the P-type silicon substrate. The front electrode is formed by metal, which inevitably covers the N-type-doped layer underneath. As a consequence, the amount of the photons incident to the N-type-doped layer is reduced and the energy converting efficiency of the cell is seriously affected. Further, a window layer that allows the entrance of photons is usually disposed between the front electrode and the N-type-doped layer to decrease the reflection of an incident light. Such an arrangement not only complicates the fabricating process but also increase the production costs thereof.

### SUMMARY OF THE INVENTION

The present invention provides a new P—N diode structure.

The present invention further provides an optoelectronic device of a P—N diode, which is fabricated by a simple process to reduce productions costs.

The present invention provides a diode adapted for an optoelectronic device, which comprises a P-type semiconductor substrate and an N-type transparent amorphous oxide semiconductor (TAOS) layer.

According to an embodiment of the present invention, the N-type transparent amorphous oxide semiconductor layer in the aforesaid diode is mainly formed by zinc oxide (ZnO), a mixture of tin oxide and zinc oxide (hereafter “a ZnO—SnO₂ mixture”), or a mixture of zinc oxide and indium oxide (hereafter “a ZnO—In₂O₃ mixture”), and further comprises other elements. The aforesaid other elements comprise aluminum, gallium, indium, boron, yttrium, scandium, fluorine, vanadium, silicon, germanium, zirconium, hafnium, nitrogen, beryllium, or a combination thereof.

According to an embodiment of the present invention, the P-type semiconductor substrate in the aforesaid diode comprises a P-type silicon wafer, a P-type silicon film, or other P-type semiconductor materials.

The present invention further provides an optoelectronic device, which comprises a P-type semiconductor substrate, an N-type transparent amorphous oxide semiconductor layer, and a rear electrode. The N-type transparent amorphous oxide semiconductor layer is disposed on a surface of the P-type semiconductor substrate. The N-type transparent amorphous oxide semiconductor layer and the P-type semiconductor substrate construct a P—N diode. The rear electrode is disposed on another surface of the P-type semiconductor substrate.

According to an embodiment of the present invention, the N-type transparent amorphous oxide semiconductor layer in the aforesaid optoelectronic device serves as a window layer and a front electrode layer.

According to an embodiment of the present invention, the N-type transparent amorphous oxide semiconductor layer in the aforesaid optoelectronic device is mainly formed by ZnO, a ZnO—SnO₂ mixture, or a ZnO—In₂O₃ mixture, and further comprises other elements. The aforesaid other elements comprise aluminum, gallium, indium, boron, yttrium, scandium, fluorine, vanadium, silicon, germanium, zirconium, hafnium, nitrogen, beryllium, or a combination thereof. According to an embodiment of the present invention, the N-type transparent amorphous oxide semiconductor layer in the aforesaid optoelectronic device is formed by a single conductive material layer.

According to an embodiment of the present invention, the N-type transparent amorphous oxide semiconductor layer in the aforesaid optoelectronic device consists of two material layers having the same conduction types but with different conductivities, wherein the material layer having lower conductivity is close to the P-type semiconductor substrate.

According to an embodiment of the present invention, the N-type transparent amorphous oxide semiconductor layer in the aforesaid optoelectronic device is formed by a material layer having conductivity gradient, wherein a portion of the material layer, which has lower conductivity, is close to the P-type semiconductor substrate while another portion, which has higher conductivity, is away from the P-type semiconductor substrate.

According to an embodiment of the present invention, the aforesaid optoelectronic device further comprises the front electrode layer formed by a metal, a transparent conductive oxide, or a combination thereof. The front electrode layer is disposed on the transparent amorphous oxide semiconductor layer.

According to an embodiment of the present invention, the metal for forming the front electrode layer comprises aluminum, silver, molybdenum, titanium, iron, copper, silver, manganese, cobalt, nickel, gold, zinc, tin, indium, chromium, platinum, tungsten, or an alloy thereof.

According to an embodiment of the present invention, the transparent conductive oxide for forming the front electrode layer comprises indium tin oxide, fluorin-doped tin oxide, aluminum-doped zinc oxide, gallium-doped zinc oxide, or a combination thereof.

According to an embodiment of the present invention, the P-type semiconductor substrate in the aforesaid optoelectronic device comprises a P-type silicon wafer, a P-type silicon film, or other P-type semiconductor materials.

According to an embodiment of the present invention, the optoelectronic device is a solar cell.

The P—N diode of the present invention is applicable in the optoelectronic device.

The optoelectronic device of the present invention is fabricated by a simpler process and requires less material, which reduce production costs.

To make the above and other objectives, features, and advantages of the present invention more comprehensible, preferable embodiments accompanied with figures are detailed as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a diode adapted for an optoelectronic device according to an embodiment of the present invention.

FIG. 2 is a schematic cross-sectional view of a transparent solar cell according to an embodiment of the present invention.

FIG. 3 is a schematic cross-sectional view of a transparent solar cell according to another embodiment of the present invention.

FIG. 4 is a schematic cross-sectional view of a transparent solar cell according to yet another embodiment of the present invention.

FIG. 5 is a schematic cross-sectional view of a transparent solar cell according to yet another embodiment of the present invention.

FIG. 6 illustrates the output characteristic curves of current versus voltage by a diode according to an embodiment of the present invention.

FIG. 7 illustrates the output characteristic curves of current versus voltage by a solar cell according to an embodiment of the present invention.

FIG. 8 is a diagram illustrating the relationship between the reflectance versus wavelength, measured by a fluorescence spectrophotometer, of a solar cell according to an embodiment of the present invention and a P-type silicon wafer.

### DESCRIPTION OF EMBODIMENTS

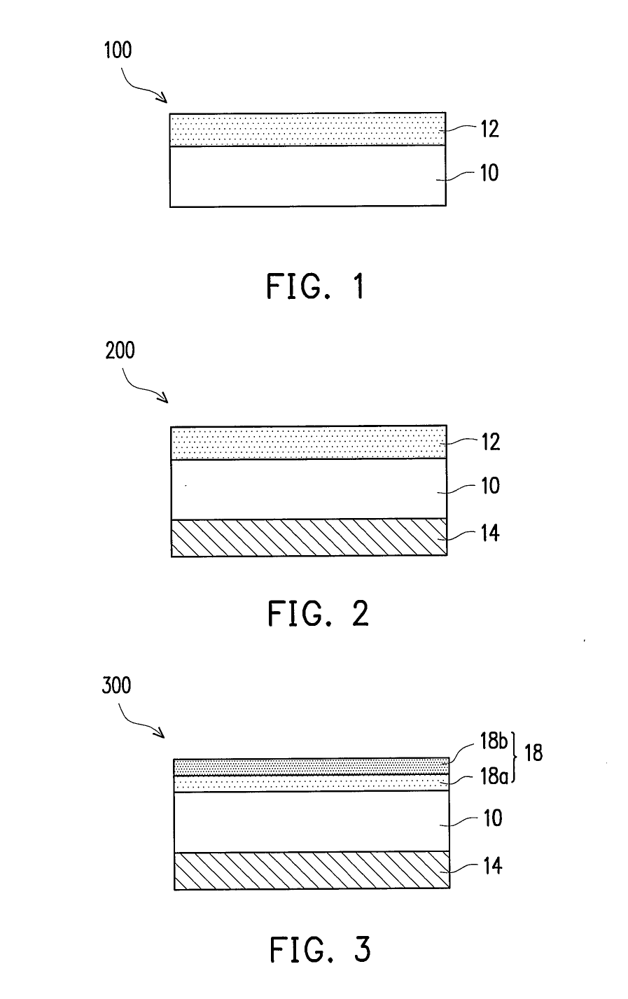

FIG. 1 is a schematic cross-sectional view of a diode adapted for an optoelectronic device according to an embodiment of the present invention.

Referring to FIG. 1, a diode 100 in this embodiment comprises a P-type semiconductor substrate 10 and an N-type transparent amorphous oxide semiconductor layer 12. The P-type semiconductor substrate 10 can be a wafer or a film, for example, a P-type silicon wafer or a P-type silicon film. The P-type semiconductor substrate 10 can also be made of other P-type semiconductor materials. The N-type transparent amorphous oxide semiconductor layer 12 is disposed on the P-type semiconductor substrate. The N-type transparent amorphous oxide semiconductor layer 12 is, for example, mainly formed by ZnO, a ZnO—SnO₂ mixture, or a ZnO—In₂O₃ mixture, and further comprises other elements. The aforesaid other elements comprise aluminum, gallium, indium, boron, yttrium, scandium, fluorine, vanadium, silicon, germanium, zirconium, hafnium, nitrogen, beryllium, or a combination thereof.

In this embodiment, the N-type transparent amorphous oxide semiconductor layer 12 is formed by aluminum-doped zinc oxide (ZnO:Al). The N-type transparent amorphous oxide semiconductor layer 12 can be formed by physical vapor deposition (PVD), chemical vapor deposition (CVD), a spin coating process, a sol-gel process, or a sputtering process.

The aforesaid diode is applicable in an optoelectronic device. In the following embodiment, a solar cell is taken as an example to explain the applications of the diode.

FIG. 2 is a schematic cross-sectional view of a solar cell according to an embodiment of the present invention.

Referring to FIG. 2, a solar cell 200 in this embodiment consists of the P-type semiconductor substrate 10, a rear electrode 14, and the N-type transparent amorphous oxide semiconductor layer 12. The P-type semiconductor substrate 10 can be a wafer or a film formed by a P-type semiconductor, for example, a P-type silicon wafer or a P-type silicon film. The P-type semiconductor substrate 10 can also be formed by other P-type semiconductor materials. The rear electrode 14 is disposed on a surface of the P-type semiconductor substrate 10, and is formed by a metal, a transparent conductive oxide (TCO), or a combination thereof. The metal is, for example, aluminum, silver, molybdenum, titanium, iron, copper, silver, manganese, cobalt, nickel, gold, zinc, tin, indium, chromium, platinum, tungsten, or an alloy thereof. The transparent conductive oxide is, for example, formed by indium tin oxide, fluorin-doped tin oxide, aluminum-doped zinc oxide, gallium-doped zinc oxide, or a combination thereof.

The N-type transparent amorphous oxide semiconductor layer 12 is disposed on another surface of the P-type semiconductor substrate 10. In addition, the N-type transparent amorphous oxide semiconductor layer 12 is, for example, mainly formed by ZnO, a ZnO—SnO₂ mixture, or a ZnO—In₂O₃ mixture, and further comprises other elements. The aforesaid elements comprise aluminum, gallium, indium, boron, yttrium, scandium, fluorine, vanadium, silicon, germanium, zirconium, hafnium, nitrogen, beryllium, or a combination thereof. In this embodiment, the N-type transparent amorphous oxide semiconductor layer 12 is, for example, formed by aluminum-doped zinc oxide (ZnO:Al).

In this embodiment, the N-type transparent amorphous oxide semiconductor layer 12 and the P-type semiconductor substrate 10 construct a P—N diode, which serves as a photoelectric conversion device. In addition, the N-type transparent amorphous oxide semiconductor layer 12 also serves as a window layer to absorb photons and a front electrode. Hence, the solar cell of this embodiment does not require an additional window layer and an additional front electrode. Consequently, light can be directly incident to the N-type transparent amorphous oxide semiconductor layer 12 without being blocked by the front electrode, to generate current in a junction of the P-type semiconductor substrate 10.

Certainly, the present invention is not limited to the above embodiment. Various modifications or alterations can be made to the present invention. Other embodiments of the present invention are detailed as follows.

FIG. 3 is a schematic cross-sectional view of a transparent thin film solar cell according to another embodiment of the present invention.

Referring to FIG. 3, a transparent thin film solar cell 300 in this embodiment consists of the P-type semiconductor substrate 10, the rear electrode 14, and an N-type transparent amorphous oxide semiconductor layer 18. The material of the P-type semiconductor substrate 10 and the arrangement and material of the rear electrode 14 are the same as those in the above embodiment. The descriptions thereof are therefore omitted herein. The N-type transparent amorphous oxide semiconductor layer 18 is disposed on another surface of the P-type semiconductor substrate 10. In addition, the N-type transparent amorphous oxide semiconductor layer 18, essentially formed by an N-type material, consists of two transparent material layers 18a and 18b, which have different conductivities. The material layer 18a, which has lower conductivity, is closer to the P-type semiconductor substrate 10; the material layer 18b, which has higher conductivity, is away from the P-type semiconductor substrate 10.

In an embodiment, the components of the transparent material layer 18a having lower conductivity is the same as that of the transparent material layer 18b having higher conductivity, but the proportions of the components are varied so as to have different conductivities. The N-type transparent amorphous oxide semiconductor layer 18 is, for example, mainly formed by ZnO, a ZnO—SnO₂ mixture, or a ZnO—In₂O₃ mixture, and further comprises other elements. The aforesaid other elements comprise aluminum, gallium, indium, boron, yttrium, scandium, fluorine, vanadium, silicon, germanium, zirconium, hafnium, nitrogen, beryllium, or a combination thereof. In an embodiment, the material layer 18b of the N-type transparent amorphous oxide semiconductor layer 18 is formed by aluminum-doped zinc oxide (ZnO:Al) and the material layer 18a is also formed by aluminum-doped zinc oxide (ZnO:Al), but the oxygen content of the material layer 18b which has higher conductivity is lower. In another embodiment, the composition of the material layer 18a having lower conductivity is different from that of the material layer 18b having higher conductivity. The material layer 18a which has lower conductivity can be formed by ZnO, a ZnO—SnO₂ mixture, a ZnO—In₂O₃ mixture, or a ZnO alloy such as aluminum-doped zinc oxide (ZnO:Al). The material layer 18b which has higher conductivity can be formed by ZnO, a ZnO—SnO₂ mixture, a ZnO—In₂O₃ mixture, or a ZnO alloy such as aluminum-doped zinc oxide (ZnO:Al). In an embodiment, the material layer 18b of the N-type transparent amorphous oxide semiconductor layer 18 is formed by aluminum-doped zinc oxide (ZnO:Al) while the material layer 18a which has lower conductivity is formed by non-aluminum-poded ZnO. In another embodiment, the material layer 18b of the N-type transparent amorphous oxide semiconductor layer 18 is formed by indium tin oxide, while the material layer 18a which has lower conductivity is formed by aluminum-doped zinc oxide (ZnO:Al).

In this embodiment, the material layer 18a having lower conductivity in the N-type transparent amorphous oxide semiconductor layer 18 and the P-type semiconductor substrate 10 construct a P—N diode, which serves as a photoelectric conversion device. The material layer 18b having higher conductivity in the N-type transparent amorphous oxide semiconductor layer 18 also serves as a window layer to absorb photons and a front electrode. Hence, the solar cell of this embodiment does not require an additional window layer and an additional front electrode. As a consequence, light can be directly incident to the N-type transparent amorphous oxide semiconductor layer 18 without being blocked by the front electrode, to generate current in a junction of the P-type semiconductor substrate 10.

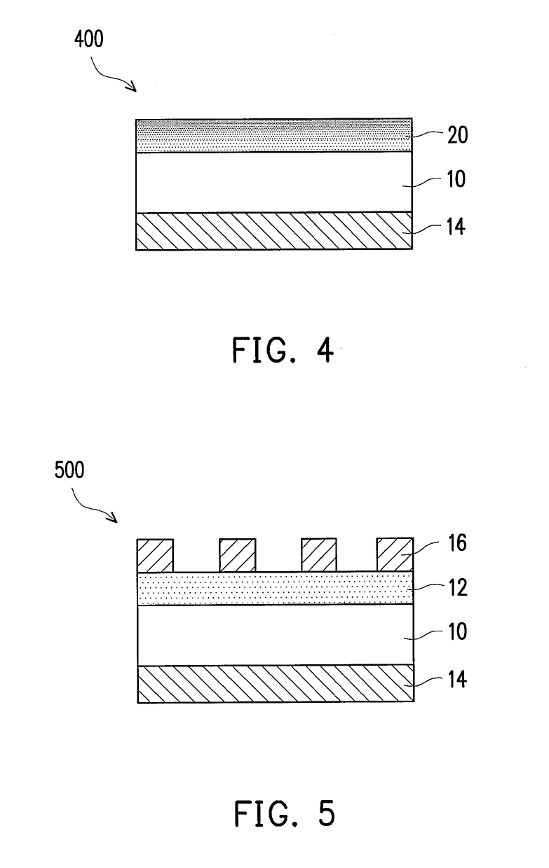

FIG. 4 is a schematic cross-sectional view of a solar cell according to another embodiment of the present invention.

Referring to FIG. 4, a transparent thin film solar cell 400 of this embodiment comprises the P-type semiconductor substrate 10, the rear electrode 14, and an N-type transparent amorphous oxide semiconductor layer 20. The material of the P-type semiconductor substrate 10 and the arrangement and material of the rear electrode 14 in this embodiment are similar to those in the embodiment of FIG. 2. The descriptions thereof are therefore omitted herein. The difference between this embodiment and the embodiment of FIG. 2 lies in the N-type transparent amorphous oxide semiconductor layer 20. Similarly, the N-type transparent amorphous oxide semiconductor layer 20 is also disposed on another surface of the P-type semiconductor substrate 10 and essentially formed by an N-type material. However, the N-type transparent amorphous oxide semiconductor layer 20 is formed by a material layer having conductivity gradient distribute in the N-type transparent amorphous oxide semiconductor layer 20. In the N-type transparent amorphous oxide semiconductor layer 20, a portion closer to the P-type semiconductor substrate 10 has lower conductivity; while another portion which is away from the P-type semiconductor substrate 10 has higher conductivity. During deposition, the proportion of the composition of the N-type transparent amorphous oxide semiconductor layer 20 can be varied to have conductivity gradient in the N-type transparent amorphous oxide semiconductor layer 20. The N-type transparent amorphous oxide semiconductor layer 20 is, for example, mainly formed by ZnO, a ZnO—SnO₂ mixture, or a ZnO—In₂O₃ mixture, and further comprises other elements. The aforesaid other elements comprise aluminum, gallium, indium, boron, yttrium, scandium, fluorine, vanadium, silicon, germanium, zirconium, hafnium, nitrogen, beryllium, or a combination thereof. In this embodiment, the N-type transparent amorphous oxide semiconductor layer 20 is, for example, formed by aluminum-doped zinc oxide (ZnO:Al), wherein the proportion of oxygen atoms decreases from the portion near the P-type semiconductor substrate 10 to the portion away from the P-type semiconductor substrate 10.

In this embodiment, the portion having lower conductivity in the N-type transparent amorphous oxide semiconductor layer 20 and the P-type semiconductor substrate 10 construct a P—N diode, which serves as a photoelectric conversion device. In the N-type transparent amorphous oxide semiconductor layer 20, the portion having higher conductivity simultaneously serves as a window layer to absorb photons and a front electrode. Hence, the solar cell of this embodiment does not require an additional window layer and an additional front electrode. Consequently, light can be directly incident to the N-type transparent amorphous oxide semiconductor layer 20 without being blocked by the front electrode, to generate current in a junction of the P-type semiconductor substrate 10.

FIG. 5 is a schematic cross-sectional view of a transparent thin film solar cell according to yet another embodiment of the present invention.

Referring to FIG. 5, if the shadowed area is not the consideration, a front electrode 16 can be additionally formed on the N-type transparent amorphous oxide semiconductor layer 12 in the structure shown in FIG. 1. The front electrode 16 is, for example, formed by a metal, a transparent conductive oxide, or a combination thereof. The metal is, for example, aluminum, silver, molybdenum, titanium, iron, copper, silver, manganese, cobalt, nickel, gold, zinc, tin, indium, chromium, platinum, tungsten, or an alloy thereof. The transparent conductive oxide is, for example, formed by indium tin oxide, fluorin-doped tin oxide, aluminum-doped zinc oxide, gallium-doped zinc oxide, or a combination thereof. In other words, a transparent thin film solar cell 500 of this embodiment, the N-type transparent amorphous oxide semiconductor layer 12 is combined with the P-type semiconductor substrate 10 to construct the P—N diode which is used as a photoelectric conversion device, and meanwhile N-type transparent amorphous oxide semiconductor layer 12 serves as a window layer to absorb photons. The front electrode 16 and the rear electrode 14 can be formed by a conventional metal or transparent conductive oxide.

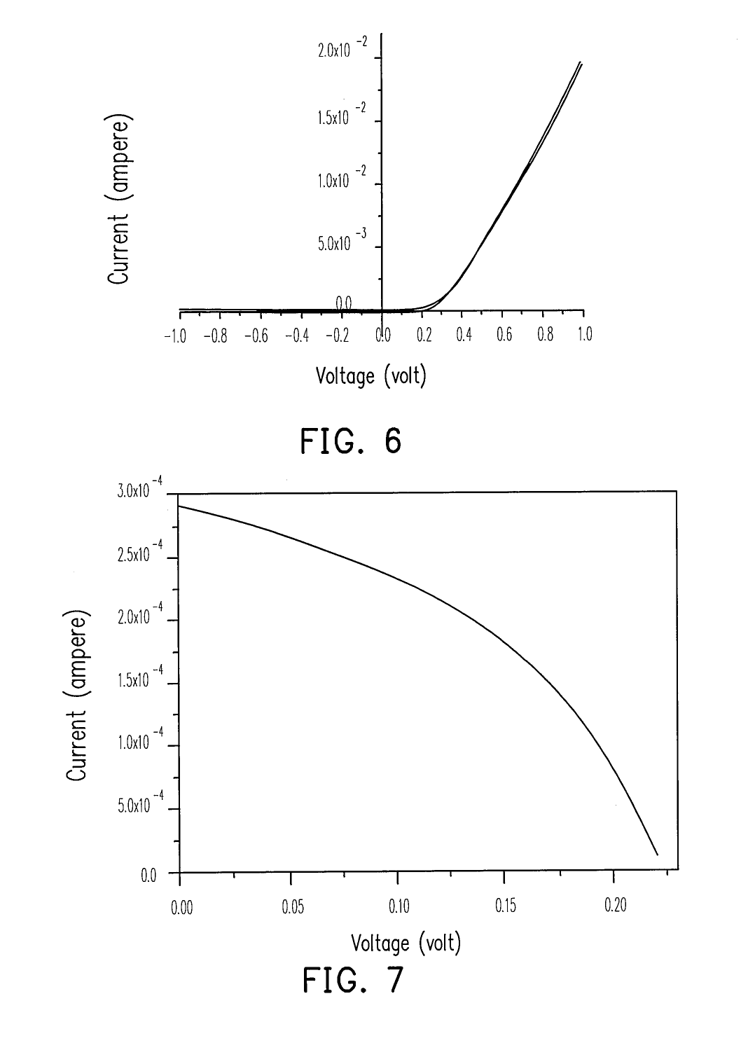

In an embodiment, a P—N diode is constructed of an N-type transparent amorphous oxide semiconductor layer formed by aluminum-doped zinc oxide (ZnO:Al) and a P-type semiconductor substrate formed by a P-type silicon wafer. Upon radiation exposure, the output characteristic curves of the P—N diode are illustrated in FIG. 6. Considering radiation exposure, the characteristic curves of the current versus voltage output from a solar cell formed by the aforesaid diode are illustrated in FIG. 7, and the data is shown in Table 1.

TABLE 1

| TAOS solar cell | Results |
|---|---|
| Work voltage Vₘ (Volt) | 0.15 |
| Maximum current Iₘ (Ampere) | 1.81 × 10⁻⁴ |
| Open voltage V_{oc} (Volt) | 0.22 |
| Short circuit current I_{sc} (Ampere) | 2.94 × 10⁻⁴ |
| Maximum output power Pₘ (Watt) | 2.71 × 10⁻⁵ |
| Filling factor FF (%) | 42.03 |
| Conversion efficiency η (%) | 0.34 |

Based on the measurement of the output current versus voltage as shown in FIG. 7, a solar cell of aluminum-doped zinc oxide has a favorable current-voltage (I-V) characteristic. It proves that light can be effectively transmitted into the junction of a P-type silicon wafer and a aluminum-doped zinc oxide film of this type of aluminum-doped zinc oxide solar cell, so as to form an internal electric field for effectively generating a photoelectric current (FF=42.03%, V_{oc}=0.22 V, J_{sc}=2.94×10⁻⁴ A/cm², η=0.34%). Based on the above measurement results, it is also known that the aluminum-doped zinc oxide film has the characteristics of an N-type semiconductor layer, and the aluminum-doped zinc oxide film can be directly deposited on the P-type silicon wafer substrate to further simplify the fabrication process of the solar cell. In addition, the opaque issue of conventional semiconductor can be overcome by using the transparent aluminum-doped zinc oxide film. Further, the top side of aluminum-doped zinc oxide on the P-type silicon wafer structure is not covered by any electrode, and therefore more visible light can be effectively incident to the PN junction to generate more current. The data in Table 1 shows that the P—N diode of the present invention is also applicable in fabricating solar cells.

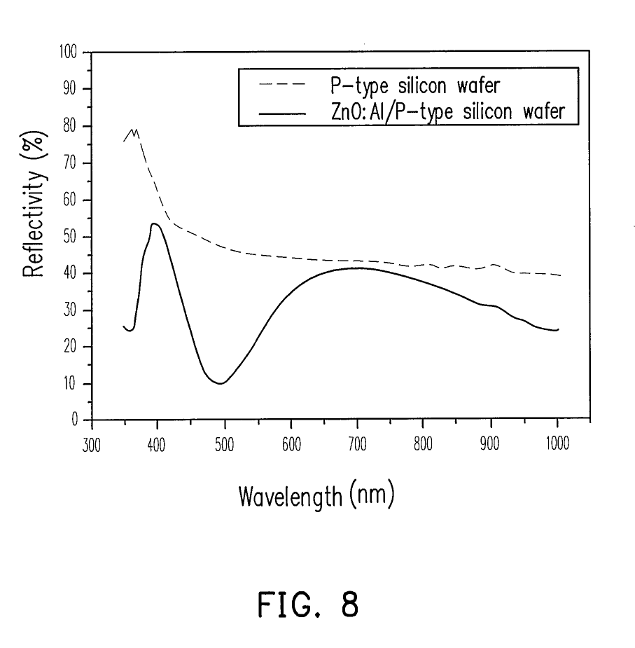

The curves in FIG. 8 respectively illustrate the relationship between the reflectance versus wavelength, measured by a fluorescence spectrophotometer, of a P-type silicon wafer and an N-type transparent amorphous oxide semiconductor layer of aluminum-doped zinc oxide deposited on the P-type silicon wafer. FIG. 8 shows that the reflectance in the range of short wavelength is low, which indicates that the aluminum-doped zinc oxide film is able to absorb short wavelength light; when compared with the P-type silicon wafer, the aluminum-doped zinc oxide film also has lower reflectance in the range of visible light. Hence, the aluminum-doped zinc oxide film is able to absorb visible light as well. The illustration of FIG. 8 proves that the reflectance is lower within the wavelength range of 350 nm˜1000 nm, which means that aluminum-doped zinc oxide is capable of absorbing a large portion of photons, and is therefore suitable to be used as a photoelectric conversion device and a window layer.

The present invention applies the P—N diode formed by the N-type transparent amorphous oxide semiconductor layer and P-type silicon wafer to the optoelectronic device, so that the device can have sufficient conversion efficiency. The N-type transparent amorphous oxide semiconductor layer provides sufficient conductivity. When applied to a solar cell, the N-type transparent amorphous oxide semiconductor layer not only constructs a portion of the P—N diode but also serves as a window layer to absorb photons and a front electrode. As a consequence, it is not required to additionally form a window layer and a front electrode. Hence, the fabricating process is simplified, the material required is reduced, and the production costs are decreased.

Although the present invention has been disclosed by the above embodiments, the present invention is not limited thereto. Persons skilled in the art may make some modifications and alterations without departing from the spirit and scope of the present invention. Hence, the protection range of the present invention falls in the appended claims.

What is claimed is:

1. A diode, comprising:
a P-type semiconductor substrate; and
an N-type transparent amorphous oxide semiconductor (TAOS) layer disposed on the P-type semiconductor substrate.

2. The diode as claimed in claim 1, wherein the N-type transparent amorphous oxide semiconductor layer is mainly formed by zinc oxide (ZnO), a mixture of tin oxide and zinc oxide (a ZnO—SnO₂ mixture), or a mixture of zinc oxide and indium oxide (a ZnO—In₂O₃ mixture), and further comprises aluminum, gallium, indium, boron, yttrium, scandium, fluorine, vanadium, silicon, germanium, zirconium, hafnium, nitrogen, beryllium, or a combination thereof.

3. The diode as claimed in claim 1, wherein the P-type semiconductor substrate comprises a P-type silicon wafer, a P-type silicon film, or other P-type semiconductor materials.

4. An optoelectronic device, comprising:
a P-type semiconductor substrate, comprising a first surface and a second surface;
a rear electrode disposed on the second surface of the P-type semiconductor substrate; and
an N-type transparent amorphous oxide semiconductor layer disposed on the first surface of the P-type semiconductor substrate, wherein the N-type transparent amorphous oxide semiconductor layer and the P-type semiconductor substrate construct a P—N diode.

5. The optoelectronic device as claimed in claim 4, wherein the N-type transparent amorphous oxide semiconductor layer serves as a window layer and a front electrode layer.

6. The optoelectronic device as claimed in claim 5, wherein the N-type transparent amorphous oxide semiconductor layer is mainly formed by ZnO, a ZnO—SnO₂ mixture, or a ZnO—In₂O₃ mixture, and further comprises aluminum, gallium, indium, boron, yttrium, scandium, fluorine, vanadium, silicon, germanium, zirconium, hafnium, nitrogen, beryllium, or a combination thereof.

7. The optoelectronic device as claimed in claim 5, wherein the N-type transparent amorphous oxide semiconductor layer is formed by a single conduction type material layer.

8. The optoelectronic device as claimed in claim 5, wherein the N-type transparent amorphous oxide semiconductor layer consists of two material layers having the same conduction types but with different conductivities, and the material layer having lower conductivity is close to the P-type semiconductor substrate.

9. The optoelectronic device as claimed in claim 5, wherein the N-type transparent amorphous oxide semiconductor layer is formed by a material layer having conductivity gradient, and a portion of the material layer, which has lower conductivity, is close to the P-type semiconductor substrate while another portion, which has higher conductivity, is away from the P-type semiconductor substrate.

10. The optoelectronic device as claimed in claim 4, further comprising a front electrode layer formed by a metal, a transparent conductive oxide, or a combination thereof, and disposed on the transparent amorphous oxide semiconductor layer.

11. The optoelectronic device as claimed in claim 10, wherein the metal comprises aluminum, silver, molybdenum, titanium, iron, copper, silver, manganese, cobalt, nickel, gold, zinc, tin, indium, chromium, platinum, tungsten, or an alloy thereof.

12. The optoelectronic device as claimed in claim 10, wherein the transparent conductive oxide comprises indium tin oxide, fluorin-doped tin oxide, aluminum-doped zinc oxide, gallium-doped zinc oxide, or a combination thereof.

13. The optoelectronic device as claimed in claim 4, wherein the P-type semiconductor substrate comprises a P-type silicon wafer, a P-type silicon film, or other P-type semiconductor materials.

14. The optoelectronic device as claimed in claim 4, wherein the optoelectronic device is a solar cell.
